(19) United States
(12) Patent Application Publication
(10) Pub. No.: US 2017/0326841 A1
(43) Pub. Date: Nov. 16, 2017

(54) Electronic Component and Process of Producing Electronic Component

(71) Applicants: TE Connectivity Corporation, Berwyn, PA (US); TE Connectivity Germany GmbH, Bensheim (DE)

(72) Inventors: Lavanya Bharadwaj, Dublin, CA (US); Barry C. Mathews, Fremont, CA (US); Dominique Freckmann, Menlo Park, CA (US); Shallu Soneja, Mountain View, CA (US); Michael A. Oar, San Francisco, CA (US); Gokce Gulsoy, San Jose, CA (US); Helge Schmidt, Speyer (DE); Michael Leidner, Lambrecht (DE); Soenke Sachs, Frankfurt am Main (DE)

(73) Assignees: TE Connectivity Corporation, Berwyn, PA (US); TE Connectivity Germany GmbH, Bensheim (DE)

(21) Appl. No.: 15/663,608

(22) Filed: Jul. 28, 2017

Related U.S. Application Data
(62) Division of application No. 14/881,041, filed on Oct. 12, 2015.

(51) Int. Cl. B32B 15/04; B32B 37/06; H05K 1/02; H01L 21/324; B32B 37/08; H05K 3/12

(52) U.S. Cl. CPC B32B 15/04; H01L 21/324; B32B 37/08; B32B 37/06; H05K 1/0207; B32B 2307/554; B32B 2457/00; H05K 3/125; H05K 2203/092; H05K 2203/1131

(57) ABSTRACT

Electronic components and processes of producing electronic components are disclosed. The electronic component includes a substrate and a thermal grain modified layer positioned on the substrate. The thermal grain modified layer includes a modified grain structure. The modified grain structure includes a thermal grain modification additive. A method for forming the electronic component is also disclosed.

### CROSS-REFERENCE TO RELATED APPLICATIONS

This application is a divisional application of co-pending, commonly assigned U.S. application Ser. No. 14/881,041, filed Oct. 12, 2015, the disclosure of which is incorporated herein by reference.

### FIELD OF THE INVENTION

The present invention is directed to electronic components and processes of producing electronic components. More particularly, the present invention is directed to energetic beam remelt components and processes.

### BACKGROUND OF THE INVENTION

Deposition of conductive inks via different printing technologies is a growing field, with limitations on compatibility for existing techniques. Such limitations render it difficult to utilize the perceived selectivity and ability to produce lower feature-sized electrical contacts. For example, reliance upon metallization techniques on printed features is problematic because they are very complicated thermodynamic and kinetic processes.

Flexibility and breadth of use for electrical contact layers is highly desirable. Prior techniques have not had sufficient control of properties associated with electrical contact layers and, thus, have been limited in application. For example, prior techniques have not adequately permitted inclusion of nanocrystalline structures and/or amorphous structures, permitted creation of medium or larger grains, permitted pore free or substantially pore free layers, permitted a gradient of elemental or compositional metals or alloys, permitted formation of a grain boundary strengthened by grain boundary engineering, permitted grain pinning, permitted higher surface hardness, permitted higher wear resistance, permitted diffusion of elements or formation of an interdiffusion layer, permitted higher corrosion resistance, or permitted combinations thereof.

Electroplating has been used to make fine grained contact surfaces which have shown improved properties in electrical contact structures. (See European Publication No. 0160761 B1, “Amorphous Transition Metal Alloy, thin gold coated, electrical contact”, published Feb. 8, 1989.)

Electroplating of electrical contacts is a common process which requires large volumes of plating bath chemicals, large area physical footprint, and consumes large quantities of precious metals. Due to environmental regulations, electroplating lines are typically segregated to specific geographic zones and undergo high levels of regulatory scrutiny. In addition, the process of electroplating is limited to a confined space for application of coating. Further, electroplated coatings result in an undesirably porous structure.

An electronic component and process of producing an electronic component that show one or more improvements in comparison to the prior art would be desirable in the art.

### BRIEF DESCRIPTION OF THE INVENTION

In an embodiment, an electronic component includes a substrate and a thermal grain modified layer positioned on the substrate. The thermal grain modified layer includes a modified grain structure. The modified grain structure includes a thermal grain modification additive.

In another embodiment, a process of producing an electronic component includes providing a substrate and applying a pre-modification layer to the substrate comprising one or more metallic components and a thermal grain modification additive. The pre-modification layer is heated and cooled to form a thermal grain modified layer.

Other features and advantages of the present invention will be apparent from the following more detailed description, taken in conjunction with the accompanying drawings which illustrate, by way of example, the principles of the invention.

### BRIEF DESCRIPTION OF THE DRAWINGS

FIG. 1 is a schematic drawing of an electrical component, according to an embodiment of the disclosure.

FIG. 2 is a schematic drawing of a method of forming an electrical component, according to an embodiment of the disclosure.

FIG. 3 is a process flow diagram of a method of forming an electrical component, according to an embodiment of the disclosure.

FIG. 4 is a micrograph of electric contact layers on embodiments of an electronic component formed via an electroplating process, according to an Example.

FIG. 5 is a micrograph of electric contact layers on embodiments of an electronic component formed via an electroplating process, according to a Comparative Example.

Wherever possible, the same reference numbers will be used throughout the drawings to represent the same parts.

### DETAILED DESCRIPTION OF THE INVENTION

Provided are electronic components and processes of producing electronic components. Embodiments of the present disclosure, for example, in comparison to concepts failing to include one or more of the features disclosed herein, permit inclusion of nanocrystalline structures and/or amorphous structures, permit creation of medium or larger grains, such as grains from about 0.5 μm to about 4 μm grains, permit pore-free or substantially pore-free layers, permit a gradient of elemental or compositional metals or alloys, permit formation of a grain boundary strengthened by grain boundary engineering via alloying element/compound additions, permit formation of a grain boundary pinning via alloying elements and insoluble particle, permit higher surface hardness, permit higher wear resistance, permit diffusion of elements or formation of an interdiffusion layer, permit higher corrosion resistance, or permit combinations thereof. The method, according to embodiments of the present disclosure, includes a process that is more environmentally friendly and includes selective deposition of precious metals that do not require electroplating. Processes, according to embodiments of the present disclosure, include higher throughput speeds, smaller footprint, and reduced precious metal consumption. In addition to process advantages, the technique generates desirable grain structures, alloys, and microstructures that provide desired physical properties. The thermal grain modified layer formed includes a surface that is smoother and less porous than electroplated surfaces. In addition, the process, according to the present disclosure, permits the inclusion of a larger selection of metals for thermal grain modified layer than can be electroplated.

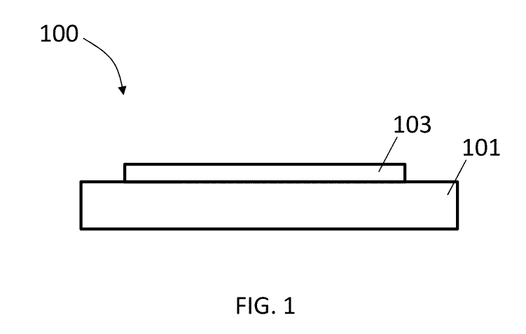

Referring to FIG. 1, according to an embodiment the disclosure, an electronic component 100 includes a substrate 101 and a thermal grain modified layer 103 present on the substrate 101. The substrate 101 is not particularly limited and may be any other conductive material compatible with the thermal grain modified layer 103. For example, suitable substrate materials include, but are not limited to, copper (Cu), copper alloys, nickel (Ni), nickel alloys, aluminum (Al), aluminum alloys, steel, steel derivatives, or combinations thereof. The thermal grain modified layer 103 is grain-refined and/or energetic beam remelted, thereby forming a thermal grain modified layer 103 having a microstructure having thermal grain modification.

Thermal grain modification, as utilized herein, is an enhancement or otherwise a modification to a metallic structure of a deposited metal. Thermal grain modification is provided by a heating and controlled cooling of a metal deposited on substrate 101 to obtain grain refinement and form preferential grain orientations. Grain refinement, as utilized herein, includes achieving small grain size by way of adding higher melting point alloying/substitutional elements or insoluble compounds. While not wishing to be bound by theory or specific explanation, these additives either act as nucleation sites for fine-sized grains during solidification (when the molten phase cools down) or pin the grain boundaries at temperatures below melting point to overcome grain growth. The grain refiner nucleants, when added to the metal alloy, give a wide range of physical and mechanical properties including high corrosion resistance, good weldability, low shrinkage, low thermal expansion, high tensile properties, good surface finish resulting in improved machinability when compared with an unmodified alloy. The increase in the strength as the grain size gets significantly smaller is believed to be related to Hall-Petch strengthening. Smaller grains have greater ratios of surface area to volume, which means the fraction of grain boundaries increases. Grain boundaries impede the dislocation slip (in general movement), which is, in general, the atomistic mechanism of plastic deformation for grain sizes greater than several nanometers.

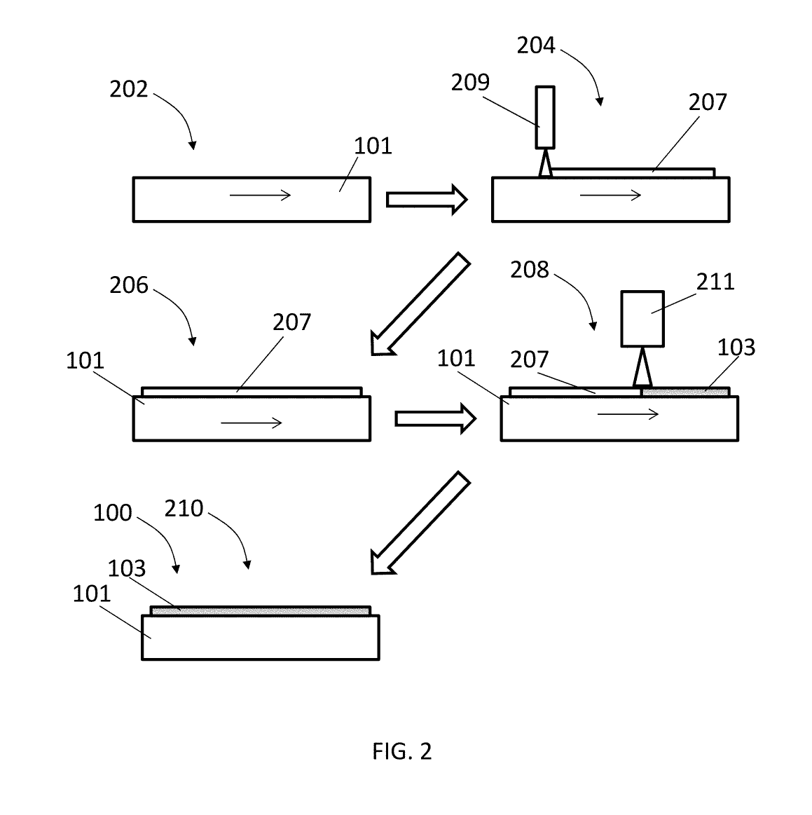

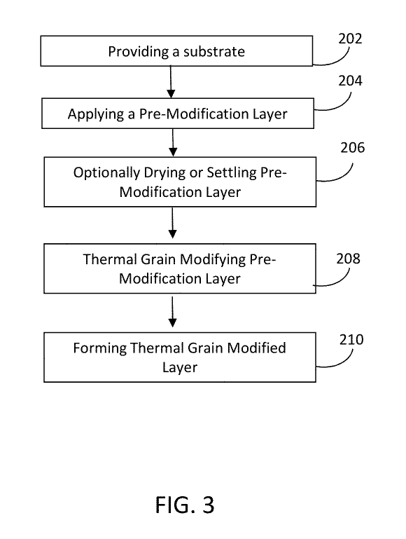

FIG. 2 shows a process of forming the electronic component 100, according to the present disclosure. As shown in FIG. 2, substrate 101 is provided (step 202), thereafter a pre-modification layer 207 containing metal is applied to substrate 101 (step 204). While the pre-modification layer 207 is shown as being applied by a printer 209, the process is not so limited. For example, in other exemplary embodiments, the pre-modification layer 207 is sprayed or rolled. In other embodiments, the pre-modification layer 207 is electroplated, printed, or otherwise applied onto the substrate 101. In certain embodiments, the pre-modification layer 207 is optionally permitted to dry or settle (step 206). After the pre-modification layer 207 has been applied (step 206), the pre-modification layer 207 is heated and cooled in a controlled manner (step 208). In the example shown in FIG. 2, the thermal grain modification is performed with heat source 211, which heats the pre-modification layer 207. In another embodiment, the heating and cooling is performed in a furnace or by energetic beam heating. Once the heating and cooling is completed, the electronic component 100 including the microstructure having a thermal grain modified microstructure is formed (step 210). The microstructure resulting from the thermal grain modification includes grain refinement and preferential formation of grain orientations. The thermal modified grains increase strength, hardness and wear resistance compared to electroplated layers. For example, in one embodiment, the coefficient of friction (CoF) for the thermal grain modified layer 103 is less than about 0.3 for 100 cycles under 50 g load.

In addition, the thermal grain modified layer 103 provides a fine grained contact finish. For example, the thermal grain modified layer 103 provides a finer grain contact finish than layers formed by electroplating.

The thermal grain modified layer 103 is formed from pre-modification layer 207. The pre-modification layer 207 includes at least one metal, alloy or metallic component and a thermal grain modification additive. For example, the pre-modification layer 207 may include metal/metallic inks/dyes/pastes or any other suitable material having the desired composition. The formulation of the pre-modification layer 207 may be any suitable ink/dye/paste formulation capable of carrying the desired metal, alloy or metallic component. For example, the pre-modification layer 207, in one embodiment, may be formed utilizing the coating layer composition of U.S. Patent Publication No. 2014/0097002 (Sachs et al.), which is hereby incorporated by reference in its entirety. Suitable metallic components for inclusion in the pre-modification layer 207 include, but are not limited to, gold (Au), silver (Ag), tin (Sn), molybdenum (Mo), titanium (Ti), palladium (Pd), platinum (Pt), rhodium (Rh), iridium (Jr), aluminum (Al), ruthenium (Ru), or combinations thereof. In addition, the pre-modification layer 207 includes a thermal grain modification additive. Thermal grain modification additives include components that provide thermal grain modification upon the heating and cooling steps, according to the present disclosure. Suitable thermal grain modification additives include, but are not limited to, solid additives, such as germanium (Ge), titanium (Ti), molybdenum (Mo), tungsten (W), tantalum (Ta), niobium (Nb), zirconium (Zr), vanadium (V), combinations thereof, or chemical additives such as nickel sulfate, nickel acetate, sodium molybdate, ammonium molybdate, organometallic complexes of W, Mo, Nb, Ta, Ti, Zr, Hf, Re, organometallic complexes of transition metals and post-transition metals, and combinations thereof.

In one embodiment, particularly suitable additives include boron, nickel acetate, nano nickel, nickel carbonate, nano molybdenum, tungstic acid, copper+germanium, titanium nitride nanoparticles, and combinations thereof. One suitable nanoparticle is an insoluble titanium nitride nanoparticle distributed within the matrix of the pre-modification layer 207. Such nanoparticles have maximum dimensions of between 10 nm and 30 nm, between 10 nm and 20 nm, between 20 nm and 30 nm, or any suitable combination, sub-combination, range, or sub-range therein.

Although not shown, a diffusion barrier layer may be applied to the substrate 101 prior to application of the pre-modification layer 207 to reduce or eliminate diffusion of the substrate material. The barrier layer includes any suitable barrier material, such as, but not limited to, nickel (Ni), titanium (Ti), molybdenum (Mo), tungsten (W), tantalum (Ta), niobium (Nb), zirconium (Zr), vanadium (V), chromium (Cr), iron (Fe), cobalt (Co), manganese (Mn), iron (Fe), hafnium (Hf), rhenium (Re), zinc (Zn), or a combination thereof. The composition of the diffusion barrier layer corresponds with the composition of the substrate and the thermal grain modified layer 103. In one embodiment, the composition of the diffusion barrier layer includes one or both of titanium and molybdenum, when the composition of the thermal grain modified layer 103 includes one or more of copper, silver and gold. In a further embodiment, the diffusion barrier layer further includes indium and/or gallium, for example, allowing the heating and cooling to be at a lower temperature, such as, below the melting point of copper.

In one embodiment, the heating and cooling is by furnace heating. In one embodiment, the thermal grain modified layer 103 is annealed. Suitable temperatures for the heating and cooling depend upon the composition used to produce the thermal grain modified layer 103. In one embodiment, the pre-modification layer 207 includes Cu and Ge and the heating is at a temperature of 1,000° C. In another embodiment, the pre-modification layer 207 includes Ag, Cu, and Ge and the heating is likewise at a temperature of 1,000° C. In other embodiments, the heating is at a temperature of between 800° C. and 1,200° C., between 900° C. and 1,100° C., between 900° C. and 1,200° C., between 800° C. and 1,100° C., or any suitable combination, sub-combination, range, or sub-range therein. For cooling, any suitable quenching or cooling may be utilized. For example, the thermal grain modified layer 103 may be furnace cooled, air cooled, quenched or otherwise cooled to form the thermal grain modified layer 103.

In one embodiment, the heating and cooling by energetic beam remelting is achieved by any suitable techniques. Suitable techniques include, but are not limited to, applying a continuous energetic beam (for example, from a CO₂ laser or electron beam welder), applying a pulsed energetic beam (for example, from a neodymium yttrium aluminum garnet laser), applying a focused beam, applying a defocused beam, or performing any other suitable beam-based technique. Energetic beam remelting is with any suitable parameters, such as, penetration depths, pulse duration, beam diameters (at contact point), beam intensity, and wavelength.

Suitable penetration depths depend upon the composition and the beam energies. For example, for Cu or Cu-containing compositions, suitable penetration depths at 20 kV include, but are not limited to, between 1 and 2 micrometers, between 1 and 1.5 micrometers, between 1.2 and 1.4 micrometers, or any suitable combination, sub-combination, range, or sub-range therein. For Cu or Cu-containing compositions, suitable penetration depths at 60 kV include, but are not limited to, between 7 and 9 micrometers, between 7.5 and 8.5 micrometers, between 7.8 and 8.2 micrometers, or any suitable combination, sub-combination, range, or sub-range therein.

For Ag or Ag-containing compositions, suitable penetration depths at 20 kV include, but are not limited to, between 1 and 2 micrometers, between 1 and 1.5 micrometers, between 1.2 and 1.4 micrometers, or any suitable combination, sub-combination, range, or sub-range therein. For Ag or Ag-containing compositions, suitable penetration depths at 60 kV include, but are not limited to, between 8 and 9 micrometers, between 8.2 and 8.8 micrometers, between 8.4 and 8.6 micrometers, or any suitable combination, sub-combination, range, or sub-range therein.

Suitable pulse durations include, but are not limited to, between 4 and 24 microseconds, between 12 and 100 microseconds, between 72 and 200 microseconds, between 100 and 300 microseconds, between 250 and 500 microseconds, between 500 and 1,000 microseconds, or any suitable combination, sub-combination, range, or sub-range therein.

Suitable beam widths include, but are not limited to, between 25 and 50 micrometers, between 30 and 40 micrometers, between 30 and 100 micrometers, between 100 and 150 micrometers, between 110 and 130 micrometers, between 120 and 140 micrometers, between 200 and 600 micrometers, between 200 and 1,000 micrometers, between 500 and 1,500 micrometers, or any suitable combination, sub-combination, range, or sub-range therein.

Suitable beam intensities include, but are not limited to, having a power output of between 2,000 watts to 10 kilowatts, between 10 kilowatts to 30 kilowatts, between 30 to 100 kilowatts, between 0.1 and 2,000 watts, between 1,100 and 1,300 watts, between 1,100 and 1,400 watts, between 1,000 and 1,300 watts, between 50 and 900 watts, between 4.5 and 60 watts, between 1 and 2 watts, between 1.2 and 1.6 watts, between 1.2 and 1.5 watts, between 1.3 and 1.5 watts, between 200 and 250 milliwatts, between 220 and 240 milliwatts, or any suitable combination, sub-combination, range, or sub-range therein.

In embodiments utilizing the laser for the energetic beam remelting, suitable wavelengths include, but are not limited to, between 10 and 11 micrometers, between 9 and 11 micrometers, between 10.5 and 10.7 micrometers, between 1 and 1.1 micrometers, between 1.02 and 1.08 micrometers, between 1.04 and 1.08 micrometers, between 1.05 and 1.07 micrometers, or any suitable combination, sub-combination, range, or sub-range therein.

In one embodiment, the thermal grain modified layer 103 has a selected concentration of Ag grains with certain orientations, for example, having a greater fraction of (111)-orientation Ag grains than (200)-orientation Ag grains. In further embodiments, the relative fraction of the (111)-orientation Ag grains to the (200)-orientation Ag grains is at a ratio of 2 to 1, at a ratio of greater than 2 to 1, at a ratio of great than 2.1 to 2, at a ratio of 2.16, or any suitable combination, sub-combination, range, or sub-range therein.

In one embodiment, the thermal grain modified layer 103 has a lower coefficient of friction than electroplated Ag (between 0.7 and 0.9). For example, suitable coefficients of friction for the thermal grain modified layer 103 include, but are not limited to, between 0.15 and 0.35, between 0.15 and 0.25, between 0.2 and 0.35, between 0.2 and 0.3, any relative value compared to the coefficient of friction of the electroplated Ag, or any suitable combination, sub-combination, range, or sub-range therein.

The Ag grains within the thermal grain modified layer 103 have dimensions and morphology corresponding with the desired application. Suitable maximum dimensions for the Ag grains include, but are not limited to, between 1 nm and 110 nm, between 90 nm and 110 nm, between 1 nm and 20 nm, between 5 nm and 15 nm, between 1 nm and 3 nm, between 1 nm and 5 nm, between 0.5 nm and 1.5 nm, or any suitable combination, sub-combination, range, or sub-range therein.

### Examples

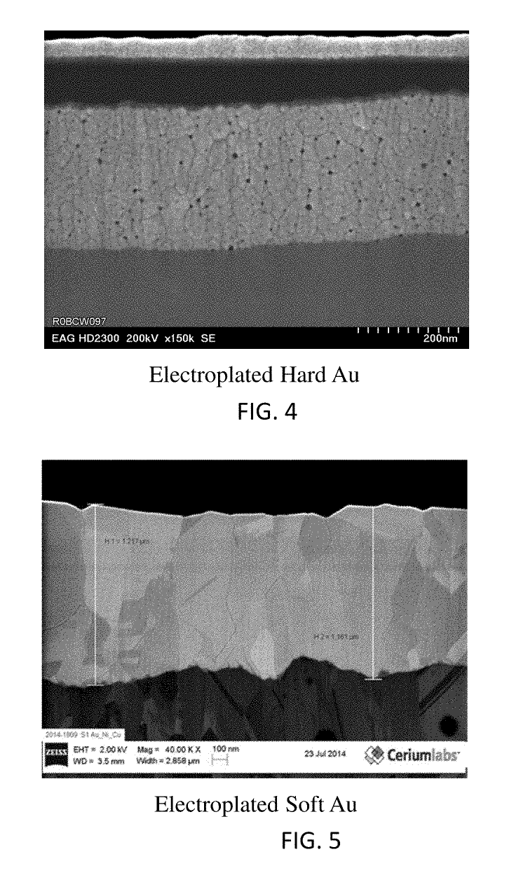

FIGS. 4-5 show layer systems for electronic contacts showing electroplated gold layers on a copper substrate. The electroplated gold layers were formed by electroplating gold from a gold cyanide bath onto the copper substrate. The gold coating layer in the Example shown in FIG. 4 was formed utilizing a gold cyanide bath including a thermal grain modification additive of cobalt sulfate. As shown in FIG. 4, the formed coating includes grain refinement. FIG. 5 is a micrograph showing an example wherein a gold coating has been electroplated on a copper substrate. The gold coating layer in the Comparative Example shown in FIG. 5 was formed utilizing a gold cyanide bath free of thermal grain modification additive. As shown in FIG. 5, the formed coating includes little or no grain refinement.

While the invention has been described with reference to one or more embodiments, it will be understood by those skilled in the art that various changes may be made and equivalents may be substituted for elements thereof without departing from the scope of the invention. In addition, many modifications may be made to adapt a particular situation or material to the teachings of the invention without departing from the essential scope thereof. Therefore, it is intended that the invention not be limited to the particular embodiment disclosed as the best mode contemplated for carrying out this invention, but that the invention will include all embodiments falling within the scope of the appended claims. In addition, all numerical values identified in the detailed description shall be interpreted as though the precise and approximate values are both expressly identified.

What is claimed is:

1. A process of producing an electronic component, the process comprising:
providing a substrate;
applying a pre-modification layer to the substrate comprising one or more metallic components and a thermal grain modification additive;
applying an energetic beam to the pre-modification layer; and
heating and cooling the pre-modification layer by the application of the energetic beam to form a thermal grain modified layer that includes a greater fraction of a (111)-grain orientation than a (200)-grain orientation.

2. The process of claim 1, wherein the thermal grain modified layer includes the (111)-orientation of grains at a ratio of at least 2 to 1 in comparison to the (200)-orientation of grains.

3. The process of claim 1, wherein the thermal grain modified layer includes silver.

4. The process of claim 1, wherein the thermal grain modification additive is selected from the group consisting of germanium, titanium, molybdenum, tungsten, tantalum, niobium, zirconium, vanadium, or combinations thereof.

5. The process of claim 1, wherein the thermal grain modification additive is selected from the group consisting of nickel sulfate, nickel acetate, sodium molybdate, ammonium molybdate, organometallic complexes of tungsten, molybdenum, niobium, tantalum, titanium, zirconium, hafnium, rhenium, organometallic complexes of transition metals and post transition metals, and combinations thereof.

6. The process of claim 1, wherein the one or more metallic components is selected from the group consisting of gold, silver, tin, molybdenum, titanium, palladium, platinum, rhodium, iridium, aluminum, ruthenium, or combinations thereof.

7. The process of claim 1, wherein the energetic beam is applied as a continuous energetic beam.

8. The process of claim 7, wherein the continuous energetic beam is from a CO₂ laser or an electron beam welder.

9. The process of claim 1, wherein the energetic beam is applied as a pulsed energetic beam.

10. The process of claim 9, wherein the pulsed energetic beam is from a neodymium yttrium aluminum garnet laser.

11. The process of claim 9, wherein the pulsed energetic beam is from a laser having a wavelength of between 9 and 11 micrometers.

12. The process of claim 1, wherein the energetic beam is a focused beam or a defocused beam.

13. The process of claim 1, further including applying a barrier layer on the substrate.

14. The process of claim 13, wherein the barrier layer comprises a material selected from the group consisting of nickel, titanium, molybdenum, tungsten, tantalum, niobium, zirconium, vanadium, chromium, iron, cobalt, manganese, iron, hafnium, rhenium, zinc, and combinations thereof.

15. The process of claim 1, wherein the thermal grain modified layer has a lower coefficient of friction/better wear resistance than electroplated silver.

16. The process of claim 1, wherein the thermal grain modified layer is an electrical contact layer.

17. The process of claim 1, wherein the thermal modified layer is composed of sub-micron and/or nanoscale grains.

18. The process of claim 1, wherein the substrate includes a material selected from the group consisting of copper, copper alloys, nickel, nickel alloys, aluminum, aluminum alloys, steel, steel derivatives, or combinations thereof.

19. The process of claim 3, wherein the energetic beam has a penetration depth at 20 kV of between 1 and 2 micrometers.

20. The process of claim 3, wherein the energetic beam has a penetration depth at 60 kV of between 8 and 9 micrometers.
